(19) United States
(12) Patent Application Publication
(10) Pub. No.: US 2022/0206101 A1
(43) Pub. Date: Jun. 30, 2022

(54) CURRENT CALIBRATION METHOD AND SYSTEM BY COMPENSATING VOLTAGE OF CURRENT SENSOR

(71) Applicant: JEE AUTOMATION EQUIPMENT (SHANGHAI) CO., LTD., Shanghai (CN)

(72) Inventors: Lei LIU, Shanghai (CN); Xue SUN, Shanghai (CN); Lin ZHANG, Shanghai (CN)

(73) Assignee: JEE AUTOMATION EQUIPMENT (SHANGHAI) CO., LTD., Shanghai (CN)

(21) Appl. No.: 17/697,652

(22) Filed: Mar. 17, 2022

Related U.S. Application Data
(63) Continuation of application No. PCT/CN2020/140697, filed on Dec. 29, 2020.

(30) Foreign Application Priority Data
Jul. 22, 2020 (CN) 202010708260.X

(51) Int. Cl. G01R 35/00; G01R 19/25

(52) U.S. Cl. CPC G01R 35/005; G01R 19/2509

(57) ABSTRACT

Disclosed are a current calibration method and a system by compensating a voltage of a current sensor, the method comprises: obtaining a power supply sampling voltage V_{cc} by performing ADC sampling on a power supply of the current sensor, and obtaining a ground plane sampling voltage V_{GND_sensor} by performing analog-to-digital converter (ADC) sampling on a voltage of the ground plane; sampling a current of the current sensor to obtain a sensor sampling voltage Vₒᵤₜ, and compensating the voltage of the current sensor to calibrate the sensor sampling voltage Vₒᵤₜ, wherein the calibrated sensor sampling voltage V_{out_correct} is:

$${V}_{out\_correct} = \frac{( {V}_{out} - {V}_{GND\_sensor} ) \cdot {V}_{nom}}{{V}_{cc} - {V}_{GND\_sensor}}$$

wherein Vₙₒₘ is a rated voltage of the power supply of the current sensor; and obtaining a calibrated sensor sampling voltage according to the calibrated sensor current value and a conversion coefficient of sampling voltage-current.

### CROSS-REFERENCE TO RELATED APPLICATIONS

This application is a continuation of International Application No. PCT/CN2020/140697, filed on Dec. 29, 2020, which claims priority to Chinese Patent Application No. 202010708260.X, filed on Jul. 22, 2020. The disclosures of the above-mentioned applications are hereby incorporated by reference in their entireties.

### TECHNICAL FIELD

The present application relates to the calibration of current sensors, in particular to a current calibration method and a system by compensating a voltage of a current sensor.

### BACKGROUND

In a closed-loop control of a current of a motor by a three-phase inverter, the performance of the torque loop directly affects the control effect of the system. Improving a control accuracy and stability of the current loop can improve the performance of the torque loop. Therefore, improving the sampling accuracy of the phase current can further improve the control accuracy of the system, so as to improve the safety performance of the system.

At present, the commonly used current sampling technologies include the sampling resistance, the transformer and the Hall sensor. However, the sampling resistance has large loss and poor stability, and the transformer has a large volume and a general accuracy. The Hall sensor is generally used in scenarios with high requirements for accuracy and stability. However, when the power supply of the Hall sensor is unstable, there will be a certain error in the output voltage of the Hall sensor, resulting in inaccurate measured current.

Since the ground plane of the current sensor may deviate from the ground plane of MCU and ADC for sampling, and the fluctuation of the power supply of the current sensor will also cause the deviation of the current sampling value, it is necessary to compensate the voltage of the current sensor to calibrate the current.

The technologies closest to this application are mainly as follows.

1. As shown in FIG. 1, the calibration current data is obtained by sampling the reference current, so as to calibrate the sampling current. This related art calibrates the other sampling current by sampling the reference current. Although the sampling accuracy of the current is improved, the reference current generation circuit is needed, which increases the cost of the circuit.

2. Comparing the measured current obtained by the ammeter with the sampling current to obtain the calibration current data, so as to calibrate the sampling current. This related art calibrates the other sampling current by the measured result of the ammeter. Each sample needs to be tested to obtain the calibration data, and the scheme is not universal.

### SUMMARY

Based on the control accuracy requirements of the system, a current calibration method and a system through voltage compensation of current sensor are designed.

On one aspect, it provides a current calibration method by compensating a voltage of a current sensor, comprising:

S1: obtaining a power supply sampling voltage V_{cc} by performing ADC sampling on a power supply of the current sensor, and obtaining a ground plane sampling voltage V_{GND_sensor} by performing ADC sampling on a voltage of the ground plane;

S2: sampling a current of the current sensor to obtain a sensor sampling voltage Vₒᵤₜ, and compensating the voltage of the current sensor to calibrate the sensor sampling voltage Vₒᵤₜ, where the calibrated sensor sampling voltage V_{out_correct} is:

$${V}_{out\_correct} = \frac{( {V}_{out} - {V}_{GND\_sensor} ) \cdot {V}_{nom}}{{V}_{cc} - {V}_{GND\_sensor}}$$

V^{nom} is a rated voltage of the power supply of the current sensor; and

S3: obtaining a calibrated sensor sampling voltage according to the calibrated sensor current value and a conversion coefficient of sampling voltage-current.

On the other aspect, it provides a current calibration system by compensating a voltage of a current sensor, comprising:

a sensor current sampling circuit configured for obtaining a sensor sampling voltage Vₒᵤₜ;

a sensor power supply sampling circuit configured for obtaining a power supply sampling voltage V_{cc};

a sensor ground plane sampling circuit configured for obtaining a ground plane sampling voltage V_{GND_sensor};

a calibration module configured for calibrating the sensor sampling voltage Vₒᵤₜ according to the power supply sampling voltage V_{cc} and the ground plane sampling voltage V_{GND_sensor}, and obtaining a calibrated sensor current value according to the calibrated sensor sampling voltage V_{GND_correct}.

According to any possible implementation of the above scheme, further, the calibration module is a MCU.

According to any possible implementation of the above scheme, further, the calibration module is a DSP.

According to any possible implementation of the above scheme, further, the sensor current sampling circuit, the sensor current sampling circuit, the sensor power supply sampling circuit and the sensor ground plane sampling circuit adopt ADC sampling and are configured for outputting digital sampling signals to the calibration module respectively.

By sampling a power supply and a ground of the current sensor and compensating the voltage of the current sensor, the sampling current can be calibrated, so as to improve an accuracy of current sampling. The advantage of the present application is to solve a problem of inaccurate current sampling caused by unstable power supply of current sensor, and is unnecessary to add additional reference current circuit and reduces a cost of the circuit.

### BRIEF DESCRIPTION OF THE DRAWINGS

The following is further described in combination with the accompanying drawings and the embodiments.

FIG. 1 is a schematic diagram of current calibration of a current sensor of related art 1.

FIG. 2 is a schematic diagram of current calibration through voltage compensation of a current sensor provided by an embodiment of the present application;

FIG. 3 is a flowchart diagram of a current calibration method by compensating a voltage of a current sensor provided by an embodiment of the present application.

### DETAILED DESCRIPTION OF THE EMBODIMENTS

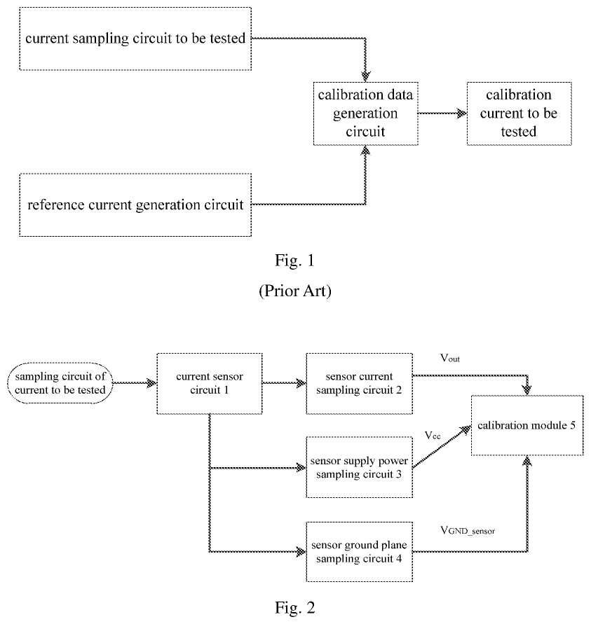

As shown in FIG. 2, an embodiment of the present application provides a current calibration system by compensating a voltage of a current sensor circuit 1, including:

a sensor current sampling circuit 2 configured for obtaining a sensor sampling voltage Vₒᵤₜ;

a sensor power supply sampling circuit 3 configured for obtaining a power supply sampling voltage V_{cc} from a power supply;

a sensor ground plane sampling circuit 4 configured for obtaining a ground plane sampling voltage V_{GND_sensor} from a ground plane;

a calibration module 5 configured for calibrating the sensor sampling voltage Vₒᵤₜ according to the power supply sampling voltage V_{cc} and the ground plane sampling voltage V_{GND_sensor}, and obtaining a calibrated sensor current value according to the calibrated sensor sampling voltage V_{GND_correct}.

The calibration module 5 uses a Microcontroller Unit (MCU) or a Digital Signal Processing (DSP) or another sampling processor device to sample a current output by the current sensor.

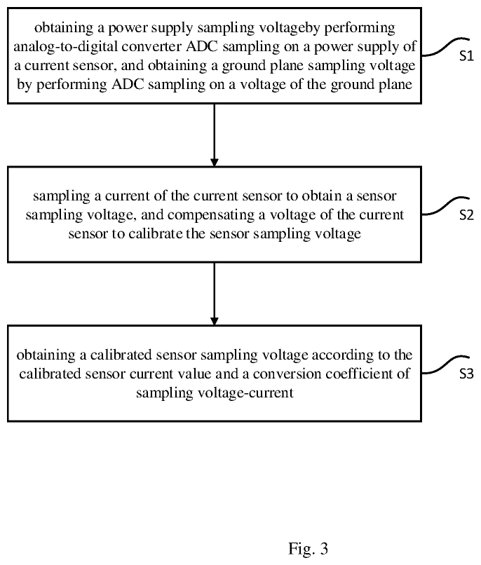

As shown in FIG. 3, the current calibration method by compensating a voltage of a current sensor provided by another embodiment of the present application includes:

S1: obtaining a power supply sampling voltage V_{cc} by performing analog-to-digital converter ADC sampling on a power supply of a current sensor, and obtaining a ground plane sampling voltage V_{GND_sensor} by performing ADC sampling on a voltage of the ground plane;

S2: sampling a current of the current sensor to obtain a sensor sampling voltage Vₒᵤₜ, and compensating a voltage of the current sensor to calibrate the sensor sampling voltage Vₒᵤₜ, where the calibrated sensor sampling voltage V_{out_correct} is :

$${V}_{out\_correct} = \frac{( {V}_{out} - {V}_{GND\_sensor} ) \cdot {V}_{nom}}{{V}_{cc} - {V}_{GND\_sensor}}$$

where Vₙₒₘ is a rated voltage of the power supply of the current sensor;

S3: obtaining a calibrated sensor sampling voltage according to the calibrated sensor current value and a conversion coefficient of sampling voltage-current.

For example, the MCU samples the current output by the current sensor to obtain the sampling voltage 2.5V, and the rated voltage of the power supply of the current sensor is 5V. The MCU samples the power supply V_{cc} and the ground plane V_{GND_sensor} of the current sensor to obtain 5.1V and 0.2V respectively. Then the calibrated sensor sampling voltage obtained by compensating the voltage of the current sensor is:

$${V}_{out\_correct} = \frac{( {V}_{out} - {V}_{GND\_sensor} ) \cdot {V}_{nom}}{{V}_{cc} - {V}_{GND\_sensor}} = \frac{( 2.5 V - 0.2 V ) \cdot 5 V}{( 5.1 V - 0.2 V )} \approx 2.35 V$$

Finally, the actual current value is obtained by converting with the conversion coefficient of the sampling voltage-current.

The above embodiment is only to illustrate the technical concept and characteristics of the present application. Its purpose is to enable the person skilled with the technology to understand the content of the present application and implement the present application. It does not limit the protection scope of the present application. Any modification made according to the spiritual essence of the main technical scheme of the present application shall be covered by the protection scope of the present application.

1. A current calibration method by compensating a voltage of a current sensor, comprising:
S1: obtaining a power supply sampling voltage V_{cc} by performing analog-to-digital converter (ADC) sampling on a power supply of the current sensor, and obtaining a ground plane sampling voltage V_{GND_sensor} by performing ADC sampling on a voltage of the ground plane;
S2: sampling a current of the current sensor to obtain a sensor sampling voltage Vₒᵤₜ, and compensating the voltage of the current sensor to calibrate the sensor sampling voltage Vₒᵤₜ, wherein the calibrated sensor sampling voltage V_{out_correct} is:
$${V}_{out\_correct} = \frac{( {V}_{out} - {V}_{GND\_sensor} ) \cdot {V}_{nom}}{{V}_{cc} - {V}_{GND\_sensor}}$$
Vₙₒₘ is a rated voltage of the power supply of the current sensor; and
S3: obtaining a calibrated sensor sampling voltage according to the calibrated sensor current value and a conversion coefficient of sampling voltage-current.

2. A current calibration system by compensating a voltage of a current sensor, comprising:
a sensor current sampling circuit configured for obtaining a sensor sampling voltage Vₒᵤₜ;
a sensor power supply sampling circuit configured for obtaining a power supply sampling voltage V_{cc};
a sensor ground plane sampling circuit configured for obtaining a ground plane sampling voltage V_{GND_sensor};
a calibration module configured for calibrating the sensor sampling voltage Vₒᵤₜ according to the power supply sampling voltage V_{cc} and the ground plane sampling voltage V_{GND_sensor}, and obtaining a calibrated sensor current value according to the calibrated sensor sampling voltage V_{GND_correct}.

3. The current calibration system according to claim 2, wherein the calibration module is a Microcontroller Unit (MCU).

4. The current calibration system according to claim 2, wherein the calibration module is a Digital Signal Processing (DSP).

5. The current calibration system according to claim 3, wherein the sensor current sampling circuit, the sensor power supply sampling circuit and the sensor ground plane sampling circuit adopt ADC sampling and are configured for outputting digital sampling signals to the calibration module.

6. The current calibration system according to claim 4, wherein the sensor current sampling circuit, the sensor power supply sampling circuit and the sensor ground plane sampling circuit adopt ADC sampling and are configured for outputting digital sampling signals to the calibration module.
